(19) United States
(12) Patent Application Publication
(10) Pub. No.: US 2026/0155044 A1
(43) Pub. Date: Jun. 4, 2026

(54) Transport Facility

(71) Applicant: Daifuku Co., Ltd., Osaka-shi (JP)

(72) Inventors: Yoshitaka Tanaka, Hinocho (JP); Kosuke Sakamoto, Hinocho (JP); Yuka Sasaki, Hinocho (JP); Tomoaki Nishikawa, Hinocho (JP)

(21) Appl. No.: 19/405,565

(22) Filed: Dec. 2, 2025

(30) Foreign Application Priority Data
Dec. 3, 2024 (JP) 2024-209970

(51) Int. Cl. G08G 1/16

(52) U.S. Cl. CPC G08G 1/164

(57) ABSTRACT

In a transport facility, a control system performs traffic control in permitting a transport vehicle at a target stop-point among stop-points or at a point upstream from the target stop-point to travel through a merging area. The control includes causing an occupancy point to enter an occupied state in which the occupancy point is occupied by a permitted transport vehicle, prohibiting, during the occupancy point being in the occupied state, transport vehicles other than the permitted transport vehicle from traveling at least from the target stop-point to the occupancy point, and canceling the occupied state after the permitted transport vehicle passes the occupancy point. During the control, the control system permits, when transport vehicles traveling to the merging area include same-path transport vehicles having a same combination of the occupancy point and a stop-point to travel through, the same-path transport vehicles to sequentially travel through the merging area.

### CROSS-REFERENCE TO RELATED APPLICATION

This application claims priority to Japanese Patent Application No. 2024-209970 filed December 3, 2024, the disclosure of which is hereby incorporated by reference in its entirety.

### BACKGROUND OF THE INVENTION

### Field of the Invention

The present invention relates to a transport facility including multiple transport vehicles, a travel path along which the multiple transport vehicles travel, and a control system that controls the multiple transport vehicles.

### Description of Related Art

An example of such a transport facility is described in Japanese Unexamined Patent Application Publication No. 2006-313463 (hereafter, JP 2006-313463). The transport facility described in JP 2006-313463 uses mutual exclusion that prohibits transport vehicles from entering a merging area including a junction on a travel path while another transport vehicle is traveling in the merging area to prevent interference between transport vehicles (refer to FIG. 3B in JP 2006-313463).

In the transport facility in JP 2006-313463, the mutual exclusion described above does not allow multiple transport vehicles to simultaneously travel through the merging area. This lowers the travel efficiency of the transport vehicles in the merging area, thus lowering the transport efficiency of the transport facility.

### SUMMARY OF THE INVENTION

Techniques are awaited for increasing the travel efficiency of the transport vehicles in the merging area to increase the transport efficiency of the transport facility.

In response to the above, a transport facility includes a plurality of transport vehicles, a travel path along which the plurality of transport vehicles travel, and a control system that controls the plurality of transport vehicles. The travel path includes a merging area including a junction at which a plurality of paths merge, a plurality of entry sections through which the plurality of transport vehicles enter the merging area, and an exit section through which the plurality of transport vehicles exit the merging area. The plurality of entry sections respectively include a plurality of stop-points. The exit section includes an occupancy point. The control system performs traffic control in permitting, among the plurality of transport vehicles, at least one transport vehicle at a target stop-point among the plurality of stop-points or at a point upstream from the target stop-point to travel through the merging area. The traffic control includes causing the occupancy point to enter an occupied state in which the occupancy point is occupied by at least one permitted transport vehicle that is the at least one transport vehicle permitted to travel through the merging area, prohibiting, during the occupancy point being in the occupied state, the plurality of transport vehicles other than the at least one permitted transport vehicle from traveling at least from the target stop-point to the occupancy point occupied by the at least one permitted transport vehicle, and canceling the occupied state after the at least one permitted transport vehicle passes the occupancy point. During the traffic control, the control system performs a sequential travel-permission process when a plurality of transport vehicles traveling to the merging area among the plurality of transport vehicles include a plurality of same-path transport vehicles having a same combination of the occupancy point and a stop-point to travel through among the plurality of stop-points. The sequential travel-permission process is a process to permit the plurality of same-path transport vehicles to sequentially travel through the merging area.

In this structure, the sequential travel-permission process can shorten the distance between the same-path transport vehicles traveling through the merging area. This allows more transport vehicles to travel through the merging area per unit time. Thus, the travel efficiency of the transport vehicles in the merging area is increased, increasing the transport efficiency of the transport facility.

### BRIEF DESCRIPTION OF THE DRAWINGS

FIG. 1 is a diagram of a transport facility according to an embodiment.

FIG. 2 is a control block diagram of the transport facility according to the embodiment.

FIG. 3 is a diagram showing a first example of traffic control performed by a control system.

FIG. 4 is a diagram showing the first example of traffic control performed by the control system.

FIG. 5 is a diagram showing the first example of traffic control performed by the control system.

FIG. 6 is a diagram showing the first example of traffic control performed by the control system.

FIG. 7 is a diagram showing the first example of traffic control performed by the control system.

FIG. 8 is a diagram showing the first example of traffic control performed by the control system.

FIG. 9 is a diagram showing a second example of traffic control performed by the control system.

FIG. 10 is a diagram showing the second example of traffic control performed by the control system.

FIG. 11 is a diagram showing the second example of traffic control performed by the control system.

FIG. 12 is a diagram showing the second example of traffic control performed by the control system.

FIG. 13 is a diagram showing the second example of traffic control performed by the control system.

FIG. 14 is a diagram showing the second example of traffic control performed by the control system.

FIG. 15 is a diagram showing a third example of traffic control performed by the control system.

FIG. 16 is a diagram showing the third example of traffic control performed by the control system.

FIG. 17 is a diagram showing the third example of traffic control performed by the control system.

FIG. 18 is a diagram showing the third example of traffic control performed by the control system.

FIG. 19 is a diagram showing the third example of traffic control performed by the control system.

FIG. 20 is a diagram showing the third example of traffic control performed by the control system.

FIG. 21 is a diagram showing a fourth example of traffic control performed by the control system.

FIG. 22 is a diagram showing the fourth example of traffic control performed by the control system.

FIG. 23 is a diagram showing the fourth example of traffic control performed by the control system.

FIG. 24 is a diagram showing the fourth example of traffic control performed by the control system.

### DESCRIPTION OF THE INVENTION

A transport facility 100 according to an embodiment will be described below with reference to the drawings.

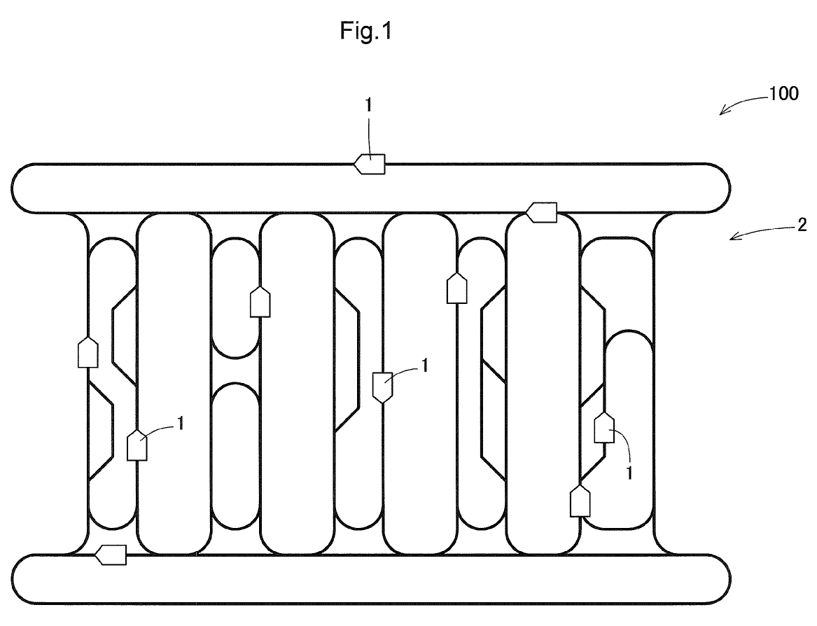

As shown in FIG. 1, the transport facility 100 includes multiple transport vehicles 1 and a travel path 2 along which the transport vehicles 1 travel.

The travel path 2 in the present embodiment is defined by a rail hung from the ceiling. In other words, the transport vehicles 1 in the present embodiment are ceiling-hung transport vehicles. The transport vehicles 1 transport articles that are, for example, front-opening unified pods (FOUPs) containing semiconductor substrates.

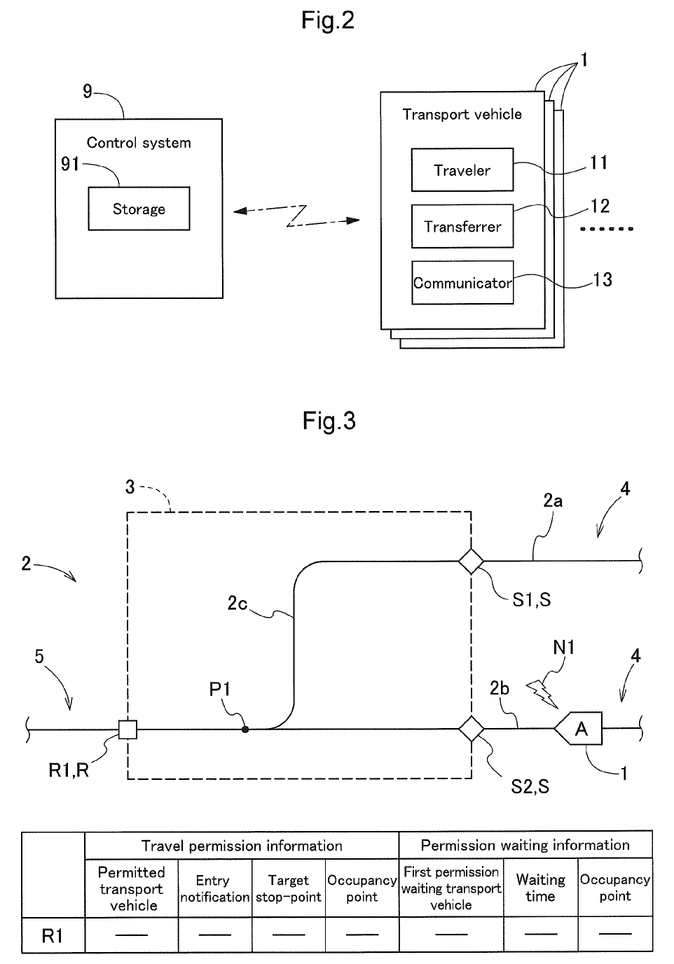

As shown in FIG. 2, the transport facility 100 includes a control system 9 that controls the multiple transport vehicles 1. The control system 9 in the present embodiment includes a storage 91 for storing various items of information. The structure of the control system 9 may be changed as appropriate.

The transport vehicles 1 in the present embodiment each include a traveler 11, a transferrer 12, and a communicator 13.

The traveler 11 includes multiple wheels that roll on the rail defining the travel path 2. At least one of the wheels is driven by a travel motor to rotate, causing the traveler 11 to travel along the travel path 2.

The transferrer 12 transfers an article to and from a predetermined transfer area. Although not described in detail, the transferrer 12 includes, for example, a holder, a lift, a horizontal mover, and a rotator. The holder holds an article. The lift lifts and lowers the holder relative to the traveler 11. The horizontal mover moves the holder horizontally relative to the traveler 11. The rotator rotates, relative to the traveler 11, the holder about a rotation axis extending in the vertical direction. The transferrer 12 may have any structure appropriate for transferring an article to and from the transfer area and is not limited to the structure described above.

The communicator 13 can communicate with the control system 9. The communicator 13 receives commands for the traveler 11 and the transferrer 12 from the control system 9. The communicator 13 transmits various notifications to the control system 9.

As shown in, for example, FIG. 3, the travel path 2 includes a merging area 3 including a junction P1 at which multiple paths merge, multiple entry sections 4 through which the transport vehicles 1 enter the merging area 3, and at least one exit section 5 through which the transport vehicles 1 exit the merging area 3. Each entry section 4 includes a stop-point S. Each exit section 5 includes an occupancy point R. In the present embodiment, each stop-point S is at a connection point of the corresponding entry section 4 and the merging area 3. The occupancy point R is at a connection point of the exit section 5 and the merging area 3.

The control system 9 performs traffic control of the transport vehicles 1 traveling to the merging area 3. The traffic control is performed when the control system 9 permits a transport vehicle 1 at a target stop-point St among the multiple stop-points S or at a point upstream from the target stop-point St to travel through the merging area 3. The traffic control includes causing the occupancy point R to enter an occupied state in which the occupancy point R is occupied by a permitted transport vehicle 1p that is the transport vehicle 1 permitted to travel through the merging area 3, prohibiting, during the occupancy point R being in the occupied state, the transport vehicles 1 other than the permitted transport vehicle 1p from traveling at least from the target stop-point St to the occupancy point R occupied by the permitted transport vehicle 1p, and canceling the occupied state after the permitted transport vehicle 1p passes the occupancy point R.

FIGS. 3 to 8 show a first example layout of the merging area 3, the entry sections 4, and the exit section 5. In this example, a single merging area 3, two entry sections 4, and a single exit section 5 are arranged.

In the example shown in FIGS. 3 to 8, the travel path 2 includes a first straight portion 2a, a second straight portion 2b, and a first connector 2c. The first straight portion 2a and the second straight portion 2b each extend straight. The first straight portion 2a and the second straight portion 2b are parallel to each other. The first connector 2c extends from the downstream end of the first straight portion 2a toward the second straight portion 2b and merges with the second straight portion 2b at the junction P1 disposed along the second straight portion 2b.

In the example shown in FIGS. 3 to 8, the first straight portion 2a includes a first stop-point S1 as the stop-point S. The second straight portion 2b includes a second stop-point S2 as the stop-point S upstream from the connection point (junction P1) of the first connector 2c and the second straight portion 2b. The second straight portion 2b includes a first occupancy point R1 as the occupancy point R downstream from the junction P1. In this example, the travel path 2 includes a path along which the transport vehicles 1 travel from the first stop-point S1 through the first straight portion 2a, the first connector 2c, and the second straight portion 2b in this order toward the first occupancy point R1, and another path along which the transport vehicles 1 travel straight from the second stop-point S2 toward the first occupancy point R1 along the second straight portion 2b.

In the example shown in FIGS. 3 to 8, the entry sections 4 include the first stop-point S1 and a section upstream from the first stop-point S1 on the first straight portion 2a as well as the second stop-point S2 and a section upstream from the second stop-point S2 on the second straight portion 2b. The exit section 5 includes the first occupancy point R1 and a section downstream from the first occupancy point R1 on the second straight portion 2b. The merging area 3 includes a section downstream from the first stop-point S1 on the first straight portion 2a, a section between the second stop-point S2 and the first occupancy point R1 on the second straight portion 2b, and the first connector 2c.

A first example of the traffic control performed by the control system 9 will now be described with reference to FIGS. 3 to 8. In this example, three transport vehicles 1 travel on the travel path 2. The three transport vehicles 1 are a first transport vehicle A, a second transport vehicle B, and a third transport vehicle C in the order of reaching the merging area 3. In this example, the first transport vehicle A and the second transport vehicle B travel straight from the second stop-point S2 toward the first occupancy point R1 along the second straight portion 2b on the travel path 2. The third transport vehicle C travels from the first stop-point S1 through the first straight portion 2a, the first connector 2c, and the second straight portion 2b in this order toward the first occupancy point R1 on the travel path 2.

As shown in FIG. 3, the first transport vehicle A first travels along the second straight portion 2b toward the second stop-point S2. The first transport vehicle A at the second stop-point S2 or at a point upstream from the second stop-point S2 then transmits a permission request N1 for permission to travel through the merging area 3 to the control system 9 through its communicator 13.

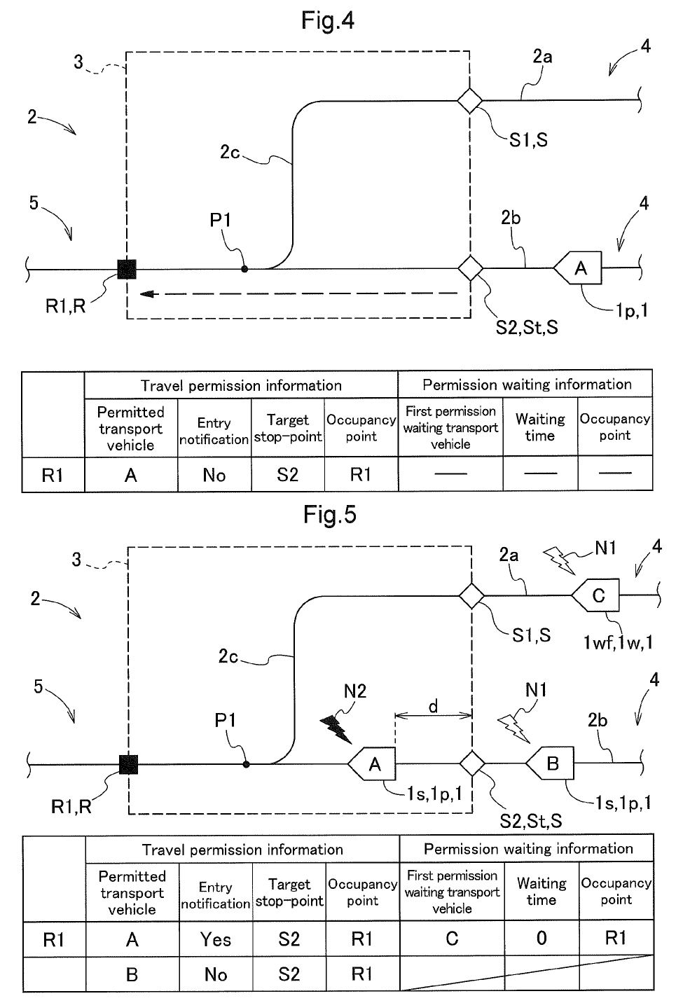

As shown in FIG. 4, in response to the permission request N1 from the first transport vehicle A, the control system 9 determines the first transport vehicle A to be the permitted transport vehicle 1p, permits the first transport vehicle A to travel from the second stop-point S2 to the first occupancy point R1 (refer to the dashed arrow in FIG. 4), and causes the first occupancy point R1 to enter the occupied state in which the first occupancy point R1 is occupied by the first transport vehicle A. The control system 9 then prohibits the transport vehicles 1 other than the first transport vehicle A from traveling from the second stop-point S2 to the first occupancy point R1. In this example, the control system 9 also prohibits the transport vehicles 1 from traveling from the first stop-point S1 to the first occupancy point R1. In FIG. 3 and subsequent figures, the occupancy point R indicated with a solid square is in the occupied state and the occupancy point R indicated with an outlined square is not in the occupied state.

The control system 9 stores travel permission information about multiple permitted transport vehicles 1p into the storage 91. The travel permission information includes information indicating the stop-point S (target stop-point St) and the occupancy point R to be traveled through by each permitted transport vehicle 1p. In this example, the travel permission information includes the identification number of the permitted transport vehicle 1p, the address of each of the stop-point S (target stop-point St) and the occupancy point R to be traveled through by the permitted transport vehicle 1p, and information indicating whether the permitted transport vehicle 1p has transmitted an entry notification N2 (described later). The travel permission information is stored for each occupancy point R. When multiple permitted transport vehicles 1p travel toward a single occupancy point R, the travel permission information about each of the multiple permitted transport vehicles 1p is stored. In FIG. 3 and subsequent figures, the situation in which a permitted transport vehicle 1p has not transmitted the entry notification N2 is indicated with No, and the situation in which a permitted transport vehicle 1p has transmitted the entry notification N2 is indicated with Yes.

After permitting the first transport vehicle A to travel from the second stop-point S2 to the first occupancy point R1 as shown in FIG. 4, the control system 9 stores, into the storage 91, the travel permission information about the first occupancy point R1. The travel permission information includes the identification number of the first transport vehicle A as the permitted transport vehicle 1p, information indicating that the first transport vehicle A has not transmitted the entry notification N2, the address of the second stop-point S2 as the stop-point S (target stop-point St) to be traveled through by the first transport vehicle A, and the address of the first occupancy point R1 as the occupancy point R to be traveled through by the first transport vehicle A.

The first transport vehicle A transmits, through its communicator 13, the entry notification N2 to the control system 9 on condition that the first transport vehicle A has traveled a set distance d from the second stop-point S2, as shown in FIG. 5. In response to the entry notification N2 from the first transport vehicle A, the control system 9 stores, into the storage 91, the travel permission information about the first occupancy point R1 indicating that the first transport vehicle A has transmitted the entry notification N2. The set distance d may be determined as appropriate based on, for example, the path to be traveled through by each transport vehicle 1. The permitted transport vehicle 1p (the first transport vehicle A in this example) may transmit the entry notification N2 immediately after traveling the set distance d from the target stop-point St (the second stop-point S2 in this example) or after satisfying an additional condition.

The second transport vehicle B as a following vehicle of the first transport vehicle A travels along the second straight portion 2b toward the second stop-point S2, and the third transport vehicle C travels along the first straight portion 2a toward the first stop-point S1. The communicator 13 in the second transport vehicle B transmits the permission request N1 to the control system 9, and then the communicator 13 in the third transport vehicle C transmits the permission request N1 to the control system 9.

In this state, the first occupancy point R1 is in the occupied state in which the first occupancy point R1 is occupied by the first transport vehicle A. Thus, the transport vehicles 1 other than the first transport vehicle A as the permitted transport vehicle 1p are prohibited from traveling from the second stop-point S2 as the target stop-point St to the first occupancy point R1. The control system 9 performs, during the traffic control, a sequential travel-permission process when the multiple transport vehicles 1 traveling to the merging area 3 include multiple same-path transport vehicles 1s having the same combination of the occupancy point R and the stop-point S to travel through among the multiple stop-points S. The sequential travel-permission process is a process to permit the multiple same-path transport vehicles 1s to sequentially travel through the merging area 3. During the sequential travel-permission process in the present embodiment, the control system 9 permits, in response to the entry notification N2, a transport vehicle 1 following the permitted transport vehicle 1p that has transmitted the entry notification N2 among the multiple same-path transport vehicles 1s to travel through the merging area 3.

In this example, the first transport vehicle A and the second transport vehicle B are the same-path transport vehicles 1s. The control system 9 that has received the entry notification N2 from the first transport vehicle A determines, in response to the permission request N1 from the second transport vehicle B, the second transport vehicle B that is the transport vehicle 1 following the first transport vehicle A to be the permitted transport vehicle 1p and permits the second transport vehicle B to travel from the second stop-point S2 to the first occupancy point R1. The control system 9 then stores, into the storage 91, the travel permission information about the first occupancy point R1. The travel permission information includes the identification number of the second transport vehicle B as the permitted transport vehicle 1p, information indicating that the second transport vehicle B has not transmitted the entry notification N2, the address of the second stop-point S2 as the stop-point S (target stop-point St) to be traveled through by the second transport vehicle B, and the address of the first occupancy point R1 as the occupancy point R to be traveled through by the second transport vehicle B.

Each of the multiple transport vehicles 1 includes a collision avoidance sensor for detecting another transport vehicle 1 in front of the transport vehicle 1. Thus, a following transport vehicle 1 (the second transport vehicle B in this example) among the same-path transport vehicles 1s can avoid colliding with a preceding transport vehicle 1 (the first transport vehicle A in this example) with the collision avoidance sensor.

In this example, the control system 9 causes the first occupancy point R1 to enter the occupied state and prohibits the transport vehicles 1 other than the permitted transport vehicle 1p from traveling from the first stop-point S1 to the first occupancy point R1. In other words, the third transport vehicle C is prohibited from traveling from the first stop-point S1 to the first occupancy point R1 until the occupied state of the first occupancy point R1 is canceled.

The control system 9 stores permission waiting information about a permission waiting transport vehicle 1w that is a transport vehicle 1 that has transmitted the permission request N1 and has not been permitted to travel through the merging area 3. The permission waiting information includes information indicating the occupancy point R to be traveled through by the permission waiting transport vehicle 1w and information indicating an elapsed time (waiting time) after the permission waiting transport vehicle 1w has transmitted the permission request N1. In this example, the permission waiting information includes the identification number of a first permission waiting transport vehicle 1wf that is the permission waiting transport vehicle 1w with the longest elapsed time after transmitting the permission request N1 among permission waiting transport vehicles 1w to travel through the same stop-point S, the address of the occupancy point R to be traveled through by the first permission waiting transport vehicle 1wf, and the elapsed time after the first permission waiting transport vehicle 1wf has transmitted the permission request N1. The permission waiting information is stored for each occupancy point R.

In this example, the control system 9 does not permit the third transport vehicle C to travel from the first stop-point S1 to the first occupancy point R1 when receiving the permission request N1 from the third transport vehicle C. The control system 9 stores, into the storage 91, the permission waiting information about the first occupancy point R1 including the identification number of the third transport vehicle C as the first permission waiting transport vehicle 1wf, the elapsed time after the third transport vehicle C has transmitted the permission request N1, and the address of the first occupancy point R1 as the occupancy point R to be traveled through by the third transport vehicle C.

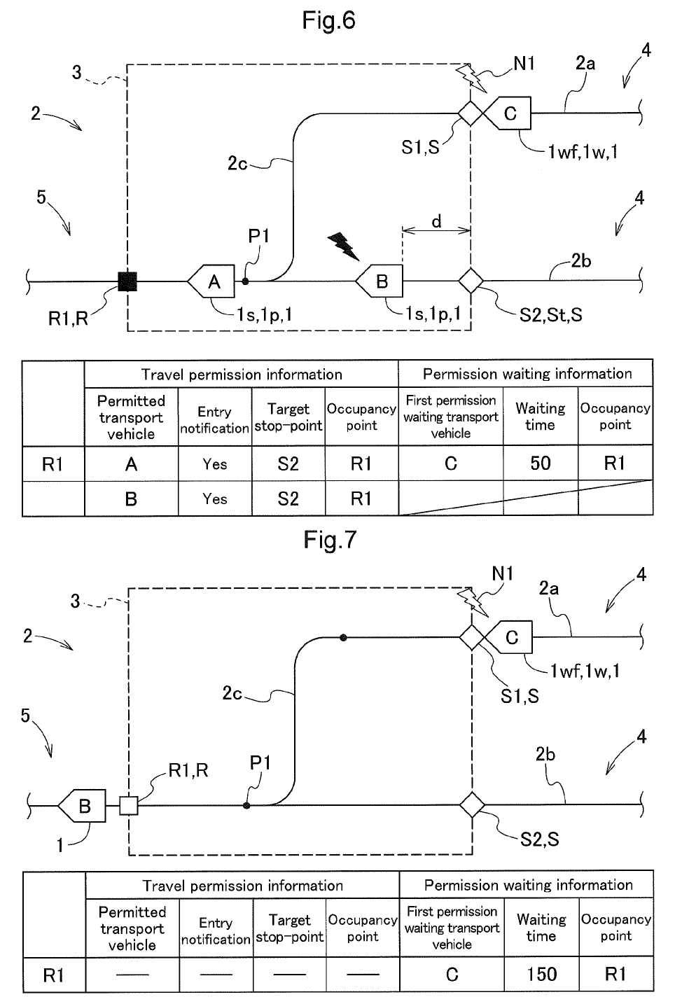

The second transport vehicle B transmits, through its communicator 13, the entry notification N2 to the control system 9 on condition that the second transport vehicle B has traveled the set distance d from the second stop-point S2, as shown in FIG. 6. In response to the entry notification N2 from the second transport vehicle B, the control system 9 stores, into the storage 91, the travel permission information about the first occupancy point R1 indicating that the second transport vehicle B has transmitted the entry notification N2.

The third transport vehicle C as the first permission waiting transport vehicle 1wf prohibited from traveling from the first stop-point S1 to the first occupancy point R1 stops at the first stop-point S1. The control system 9 then updates the permission waiting information about the third transport vehicle C (the elapsed time after the third transport vehicle C has transmitted the permission request N1 in this example) stored in the storage 91. In this example, the permission waiting transport vehicle 1w continuously or intermittently transmits the permission request N1 to the control system 9 until permitted by the control system 9 to travel through the merging area 3.

After the first transport vehicle A and the second transport vehicle B as the permitted transport vehicles 1p pass the first occupancy point R1, the control system 9 cancels the occupied state of the first occupancy point R1 as shown in FIG. 7. The control system 9 then deletes the travel permission information about the first transport vehicle A and the second transport vehicle B. The control system 9 also updates the permission waiting information about the third transport vehicle C (the elapsed time after the third transport vehicle C has transmitted the permission request N1 in this example) stored in the storage 91.

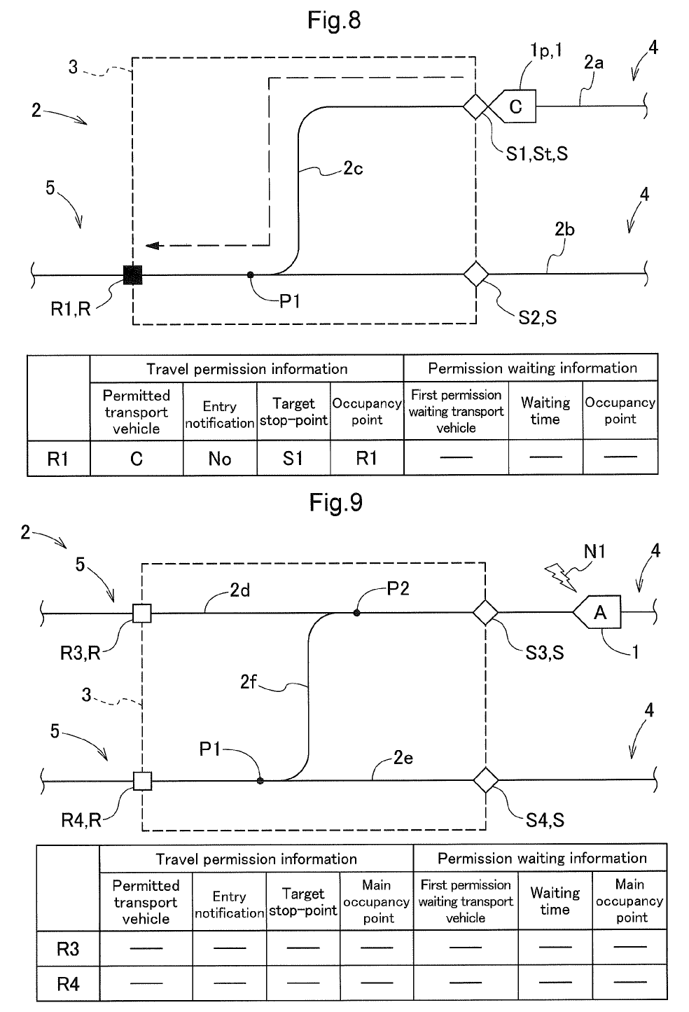

Subsequently, in response to the permission request N1 from the third transport vehicle C as the first permission waiting transport vehicle 1wf, the control system 9 determines the third transport vehicle C to be the permitted transport vehicle 1p, permits the third transport vehicle C to travel from the first stop-point S1 to the first occupancy point R1 (refer to the dashed arrow in FIG. 8), and causes the first occupancy point R1 to enter the occupied state in which the first occupancy point R1 is occupied by the third transport vehicle C, as shown in FIG. 8. The control system 9 stores, into the storage 91, the travel permission information about the first occupancy point R1 including the identification number of the third transport vehicle C as the permitted transport vehicle 1p, information indicating that the third transport vehicle C has not transmitted the entry notification N2, the address of the first stop-point S1 as the stop-point S (target stop-point St) to be traveled through by the third transport vehicle C, and the address of the first occupancy point R1 as the occupancy point R to be traveled through by the third transport vehicle C. The subsequent operation of the control system 9 will not be described.

FIGS. 9 to 14 show a second example layout of the merging area 3, the entry sections 4, and the exit section 5. In this example, a single merging area 3, two entry sections 4, and two exit sections 5 are arranged.

In the example shown in FIGS. 9 to 14, the travel path 2 includes a third straight portion 2d, a fourth straight portion 2e, and a second connector 2f. The third straight portion 2d and the fourth straight portion 2e each extend straight. The third straight portion 2d and the fourth straight portion 2e are parallel to each other. The second connector 2f branches from the third straight portion 2d at a branch P2 disposed along the third straight portion 2d and merges with the fourth straight portion 2e at the junction P1 disposed along the fourth straight portion 2e.

In the example shown in FIGS. 9 to 14, the third straight portion 2d includes a third stop-point S3 as the stop-point S upstream from the connection point (branch P2) of the second connector 2f and the third straight portion 2d. The third straight portion 2d includes a third occupancy point R3 as the occupancy point R downstream from the branch P2. The fourth straight portion 2e includes a fourth stop-point S4 as the stop-point S upstream from the connection point (junction P1) of the second connector 2f and fourth straight portion 2e. The fourth straight portion 2e includes a fourth occupancy point R4 as the occupancy point R downstream from the junction P1. In this example, the travel path 2 includes a path along which the transport vehicles 1 travel from the third stop-point S3 toward the third occupancy point R3 along the third straight portion 2d, a path along which the transport vehicles 1 travel from the third stop-point S3 through the third straight portion 2d, the second connector 2f, and the fourth straight portion 2e in this order toward the fourth occupancy point R4, and a path along which the transport vehicles 1 travel straight from the fourth stop-point S4 toward the fourth occupancy point R4 along the fourth straight portion 2e.

In the example shown in FIGS. 9 to 14, the entry sections 4 include the third stop-point S3 and a section upstream from the third stop-point S3 on the third straight portion 2d as well as the fourth stop-point S4 and a section upstream from the fourth stop-point S4 on the fourth straight portion 2e. The exit sections 5 include the third occupancy point R3 and a section downstream from the third occupancy point R3 on the third straight portion 2d as well as the fourth occupancy point R4 and a section downstream from the fourth occupancy point R4 on the fourth straight portion 2e. The merging area 3 includes a section between the third stop-point S3 and the third occupancy point R3 on the third straight portion 2d, a section between the fourth stop-point S4 and the fourth occupancy point R4 on the fourth straight portion 2e, and the second connector 2f.

A second example of the traffic control performed by the control system 9 will now be described with reference to FIGS. 9 to 14. In this example, four transport vehicles 1 travel on the travel path 2. The four transport vehicles 1 are a first transport vehicle A, a second transport vehicle B, a third transport vehicle C, and a fourth transport vehicle D in the order of reaching the merging area 3. In this example, the first transport vehicle A and the second transport vehicle B travel on the travel path 2 from the third stop-point S3 through the third straight portion 2d, the second connector 2f, and the fourth straight portion 2e in this order toward the fourth occupancy point R4. The third transport vehicle C then travels straight from the fourth stop-point S4 toward the fourth occupancy point R4 along the fourth straight portion 2e on the travel path 2. The fourth transport vehicle D travels straight from the third stop-point S3 toward the third occupancy point R3 along the third straight portion 2d on the travel path 2.

As shown in FIG. 9, the first transport vehicle A travels along the third straight portion 2d toward the third stop-point S3 first. The first transport vehicle A at the third stop-point S3 or at a point upstream from the third stop-point S3 transmits the permission request N1 to the control system 9 through its communicator 13.

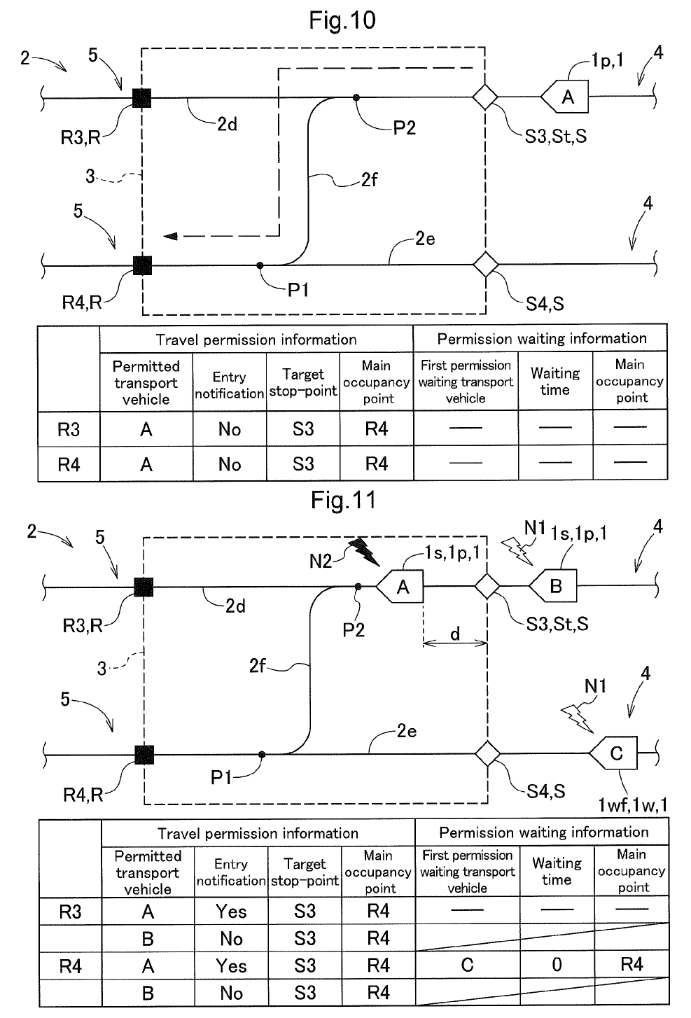

As shown in FIG. 10, in response to the permission request N1 from the first transport vehicle A, the control system 9 determines the first transport vehicle A to be the permitted transport vehicle 1p, permits the first transport vehicle A to travel from the third stop-point S3 to the fourth occupancy point R4 (refer to the dashed arrow in FIG. 10), and causes the fourth occupancy point R4 to enter the occupied state in which the fourth occupancy point R4 is occupied by the first transport vehicle A. The control system 9 then prohibits the transport vehicles 1 other than the first transport vehicle A from traveling from the third stop-point S3 to the fourth occupancy point R4. In this example, with the permitted transport vehicle 1p (the first transport vehicle A in this example) traveling along a path following the branch P2 (the second connector 2f and the fourth straight portion 2e in this example), the control system 9 causes the occupancy point R (the third occupancy point R3 in this example) disposed on a path extending straight through the branch P2 (the third straight portion 2d in this example) to enter the occupied state in addition to the occupancy point R (the fourth occupancy point R4 in this example) disposed on the path following the branch P2. In other words, the control system 9 also prohibits the transport vehicles 1 from traveling from the third stop-point S3 to the third occupancy point R3. This prevents a following transport vehicle 1 traveling straight on the path extending through the branch P2 from colliding into a preceding transport vehicle 1 traveling on the path following the branch P2 when, for example, the preceding transport vehicle 1 stops immediately after passing the branch P2. With the permitted transport vehicle 1p (the first transport vehicle A in this example) traveling on the path extending straight through the branch P2 (the third straight portion 2d in this example), only the occupancy point R (the third occupancy point R3) on the path extending straight through the branch P2 may be in the occupied state.

In the examples described hereafter, the two occupancy points R on the path connected to the branch P2 through which the permitted transport vehicle 1p passes include a main occupancy point through which the permitted transport vehicle 1p actually travels and a sub-occupancy point through which the permitted transport vehicle 1p does not travel. In this example, the fourth occupancy point R4 through which the first transport vehicle A as the permitted transport vehicle 1p actually passes corresponds to the main occupancy point, and the third occupancy point R3 corresponds to the sub-occupancy point.

After permitting the first transport vehicle A to travel from the third stop-point S3 to the fourth occupancy point R4, the control system 9 stores, into the storage 91, the travel permission information about the fourth occupancy point R4 that is the main occupancy point. The travel permission information about the fourth occupancy point R4 includes the identification number of the first transport vehicle A as the permitted transport vehicle 1p, information indicating that the first transport vehicle A has not transmitted the entry notification N2, the address of the third stop-point S3 as the stop-point S (target stop-point St) to be traveled through by the first transport vehicle A, and the address of the fourth occupancy point R4 as the occupancy point R (main occupancy point) to be traveled through by the first transport vehicle A. The control system 9 also stores, into the storage 91, the travel permission information about the third occupancy point R3 that is the sub-occupancy point. The travel permission information about the third occupancy point R3 includes the identification number of the first transport vehicle A as the permitted transport vehicle 1p, information indicating that the first transport vehicle A has not transmitted the entry notification N2, the address of the third stop-point S3 as the stop-point S (target stop-point St) to be traveled through by the first transport vehicle A, and the address of the fourth occupancy point R4 as the occupancy point R (main occupancy point) to be traveled through by the first transport vehicle A.

The first transport vehicle A transmits, through its communicator 13, the entry notification N2 to the control system 9 on condition that the first transport vehicle A has traveled a set distance d from the third stop-point S3, as shown in FIG. 11. In response to the entry notification N2 from the first transport vehicle A, the control system 9 stores, into the storage 91, the travel permission information about the fourth occupancy point R4 indicating that the first transport vehicle A has transmitted the entry notification N2. The control system 9 also stores, into the storage 91, the travel permission information about the third occupancy point R3 indicating that the first transport vehicle A has transmitted the entry notification N2.

The second transport vehicle B following the first transport vehicle A travels along the third straight portion 2d toward the third stop-point S3, and the third transport vehicle C travels along the fourth straight portion 2e toward the fourth stop-point S4. The communicator 13 in the second transport vehicle B transmits the permission request N1 to the control system 9, and the communicator 13 in the third transport vehicle C transmits the permission request N1 to the control system 9.

In this state, the fourth occupancy point R4, which is the main occupancy point, is in the occupied state in which the fourth occupancy point R4 is occupied by the first transport vehicle A. Thus, the transport vehicles 1 other than the first transport vehicle A as the permitted transport vehicle 1p are prohibited from traveling from the third stop-point S3 as the target stop-point St to the fourth occupancy point R4. However, the first transport vehicle A and the second transport vehicle B are the same-path transport vehicles 1s. The control system 9 that has received the entry notification N2 from the first transport vehicle A determines, in response to the permission request N1 from the second transport vehicle B, the second transport vehicle B that is the transport vehicle 1 following the first transport vehicle A to be the permitted transport vehicle 1p and permits the second transport vehicle B to travel from the third stop-point S3 to the fourth occupancy point R4. The control system 9 stores, into the storage 91, the travel permission information about the fourth occupancy point R4 including the identification number of the second transport vehicle B as the permitted transport vehicle 1p, information indicating that the second transport vehicle B has not transmitted the entry notification N2, the address of the third stop-point S3 as the stop-point S (target stop-point St) to be traveled through by the second transport vehicle B, and the address of the fourth occupancy point R4 as the occupancy point R to be traveled through by the second transport vehicle B. The control system 9 also stores, into the storage 91, the travel permission information about the third occupancy point R3 including the identification number of the second transport vehicle B as the permitted transport vehicle 1p, information indicating that the second transport vehicle B has not transmitted the entry notification N2, the address of the third stop-point S3 as the stop-point S (target stop-point St) to be traveled through by the second transport vehicle B, and the address of the fourth occupancy point R4 as the occupancy point R to be traveled through by the second transport vehicle B.

In this example, with the fourth occupancy point R4 in the occupied state, the control system 9 also prohibits the transport vehicles 1 from traveling from the fourth stop-point S4 to the fourth occupancy point R4. In other words, the third transport vehicle C is prohibited from traveling from the fourth stop-point S4 to the fourth occupancy point R4 until the occupied state of the fourth occupancy point R4 is canceled.

The control system 9 does not permit the third transport vehicle C to travel from the fourth stop-point S4 to the fourth occupancy point R4 when receiving the permission request N1 from the third transport vehicle C. The control system 9 stores, into the storage 91, the permission waiting information about the fourth occupancy point R4 including the identification number of the third transport vehicle C as the first permission waiting transport vehicle 1wf at the fourth stop-point S4, the elapsed time after the third transport vehicle C has transmitted the permission request N1, and the address of the fourth occupancy point R4 as the occupancy point R to be traveled through by the third transport vehicle C.

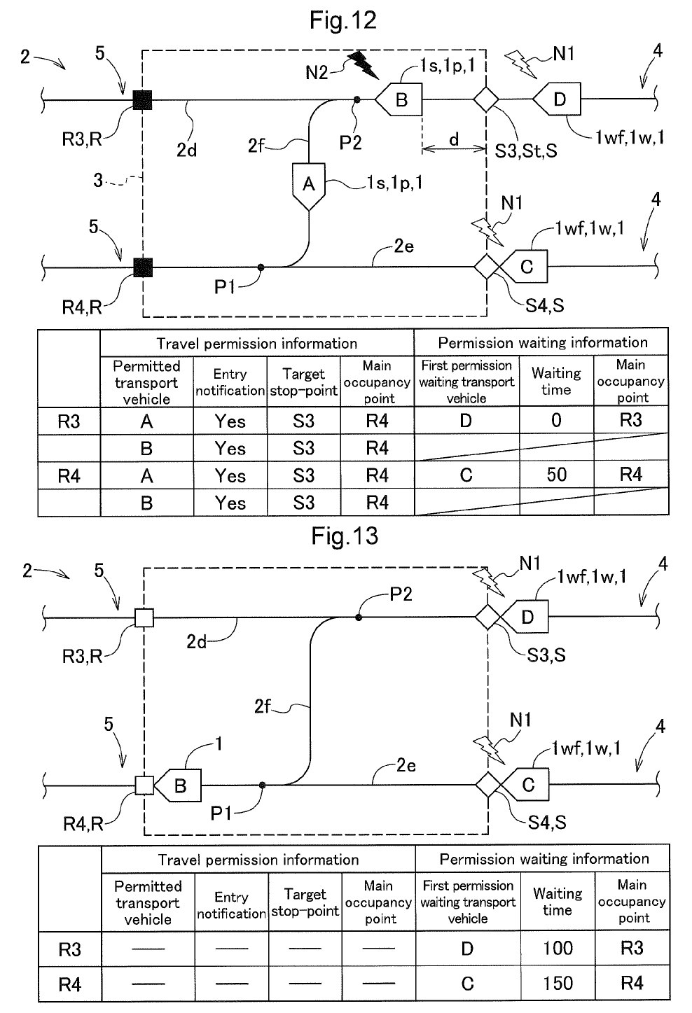

The second transport vehicle B transmits, through its communicator 13, the entry notification N2 to the control system 9 on condition that the second transport vehicle B has traveled the set distance d from the third stop-point S3, as shown in FIG. 12. In response to the entry notification N2 from the second transport vehicle B, the control system 9 stores, into the storage 91, the travel permission information about the fourth occupancy point R4 indicating that the second transport vehicle B has transmitted the entry notification N2. The control system 9 also stores, into the storage 91, the travel permission information about the third occupancy point R3 indicating that the second transport vehicle B has transmitted the entry notification N2.

The third transport vehicle C as the first permission waiting transport vehicle 1wf prohibited from traveling from the fourth stop-point S4 to the fourth occupancy point R4 stops at the fourth stop-point S4. The control system 9 then updates the permission waiting information about the third transport vehicle C (the elapsed time after the third transport vehicle C has transmitted the permission request N1 in this example) stored in the storage 91.

The fourth transport vehicle D following the second transport vehicle B also travels along the third straight portion 2d toward the third stop-point S3. The communicator 13 in the fourth transport vehicle D then transmits the permission request N1 to the control system 9.

In this state, the third occupancy point R3, which is the sub-occupancy point, is in the occupied state in which the third occupancy point R3 is occupied by the first transport vehicle A. The transport vehicles 1 are thus prohibited from traveling from the third stop-point S3 to the third occupancy point R3. The control system 9 does not permit the fourth transport vehicle D to travel from the third stop-point S3 to the third occupancy point R3 when receiving the permission request N1 from the fourth transport vehicle D. The control system 9 stores, into the storage 91, the permission waiting information about the third occupancy point R3 including the identification number of the fourth transport vehicle D as the first permission waiting transport vehicle 1wf at the third stop-point S3, the elapsed time after the fourth transport vehicle D has transmitted the permission request N1, and the address of the third occupancy point R3 as the occupancy point R to be traveled through by the fourth transport vehicle D.

When the second transport vehicle B as the permitted transport vehicle 1p traveling as the last one of the same-path transport vehicles 1s reaches the fourth occupancy point R4 or after the first transport vehicle A and the second transport vehicle B as the permitted transport vehicles 1p pass the fourth occupancy point R4, the control system 9 cancels the occupied state of the fourth occupancy point R4, which is the main occupancy point, and the third occupancy point R3, which is the sub-occupancy point, as shown in FIG. 13. The control system 9 then deletes the travel permission information about the first transport vehicle A and the second transport vehicle B. The control system 9 also updates the permission waiting information about the third transport vehicle C (the elapsed time after the third transport vehicle C has transmitted the permission request N1 in this example) and the permission waiting information about the fourth transport vehicle D (the elapsed time after the fourth transport vehicle D has transmitted the permission request N1 in this example) stored in the storage 91.

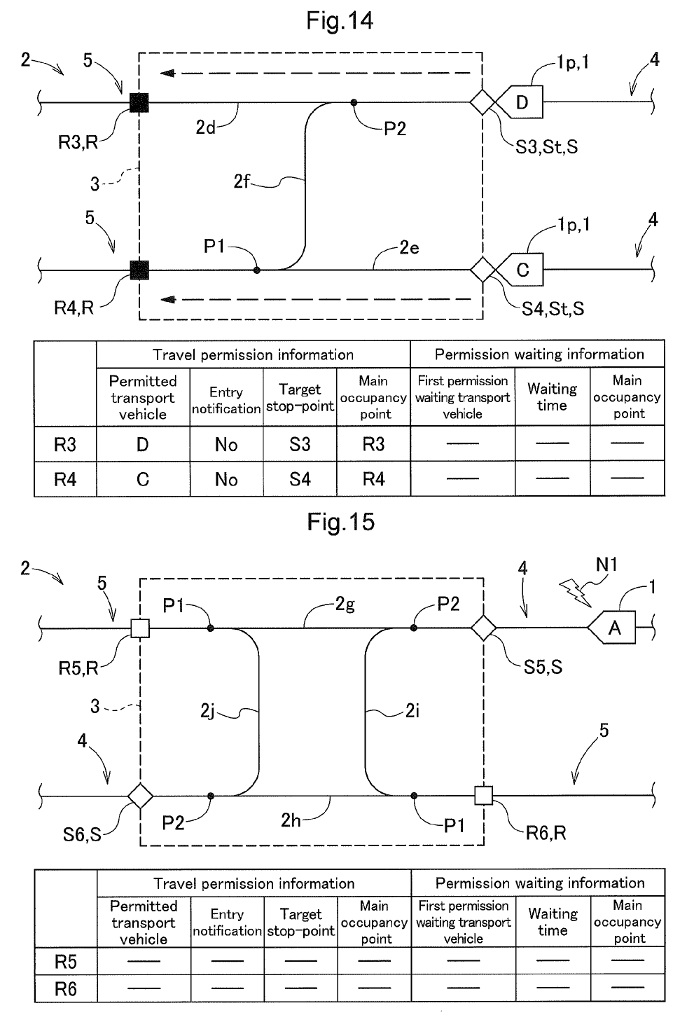

Subsequently, in response to the permission request N1 from the third transport vehicle C as the first permission waiting transport vehicle 1wf at the fourth stop-point S4, the control system 9 determines the third transport vehicle C to be the permitted transport vehicle 1p, permits the third transport vehicle C to travel from the fourth stop-point S4 to the fourth occupancy point R4 (refer to the lower dashed arrow in FIG. 14), and causes the fourth occupancy point R4 to enter the occupied state in which the fourth occupancy point R4 is occupied by the third transport vehicle C, as shown in FIG. 14. The control system 9 stores, into the storage 91, the travel permission information about the fourth occupancy point R4 including the identification number of the third transport vehicle C as the permitted transport vehicle 1p, information indicating that the third transport vehicle C has not transmitted the entry notification N2, the address of the fourth stop-point S4 as the stop-point S (target stop-point St) to be traveled through by the third transport vehicle C, and the address of the fourth occupancy point R4 as the occupancy point R to be traveled through by the third transport vehicle C.

In response to the permission request N1 from the fourth transport vehicle D as the first permission waiting transport vehicle 1wf at the third stop-point S3, the control system 9 also determines the fourth transport vehicle D to be the permitted transport vehicle 1p, permits the fourth transport vehicle D to travel from the third stop-point S3 to the third occupancy point R3 (refer to the upper dashed arrow in FIG. 14), and causes the third occupancy point R3 to enter the occupied state in which the third occupancy point R3 is occupied by the fourth transport vehicle D. The control system 9 stores, into the storage 91, the travel permission information about the third occupancy point R3 including the identification number of the fourth transport vehicle D as the permitted transport vehicle 1p, information indicating that the fourth transport vehicle D has not transmitted the entry notification N2, the address of the third stop-point S3 as the stop-point S (target stop-point St) to be traveled through by the fourth transport vehicle D, and the address of the third occupancy point R3 as the occupancy point R to be traveled through by the fourth transport vehicle D. The subsequent operation of the control system 9 will not be described.

FIGS. 15 to 20 show a third example layout of the merging area 3, the entry sections 4, and the exit section 5. In this example, a single merging area 3, two entry sections 4, and two exit sections 5 are arranged.

In the example shown in FIGS. 15 to 20, the travel path 2 includes a fifth straight portion 2g, a sixth straight portion 2h, a third connector 2i, and a fourth connector 2j. The fifth straight portion 2g and the sixth straight portion 2h each extend straight. The fifth straight portion 2g and the sixth straight portion 2h are parallel to each other. The third connector 2i branches from the fifth straight portion 2g at the branch P2 disposed along the fifth straight portion 2g and merges with the sixth straight portion 2h at the junction P1 disposed along the sixth straight portion 2h. The fourth connector 2j branches from the sixth straight portion 2h at the branch P2 disposed upstream from the junction P1 on the sixth straight portion 2h and merges with the fifth straight portion 2g at the junction P1 disposed downstream from the branch P2 on the fifth straight portion 2g.

In the example shown in FIGS. 15 to 20, the fifth straight portion 2g includes a fifth stop-point S5 as the stop-point S upstream from the connection point (branch P2) of the third connector 2i and the fifth straight portion 2g. The fifth straight portion 2g includes a fifth occupancy point R5 as the occupancy point R downstream from the connection point (junction P1) of the fourth connector 2j and the fifth straight portion 2g. The sixth straight portion 2h includes a sixth stop-point S6 as the stop-point S upstream from the connection point (branch P2) of the fourth connector 2j and the sixth straight portion 2h. The sixth straight portion 2h includes a sixth occupancy point R6 as the occupancy point R downstream from the connection point (junction P1) of the third connector 2i and the sixth straight portion 2h. In this example, the travel path 2 includes a path along which the transport vehicles 1 travel from the fifth stop-point S5 toward the fifth occupancy point R5 along the fifth straight portion 2g, a path along which the transport vehicles 1 travel from the fifth stop-point S5 through the fifth straight portion 2g, the third connector 2i, and the sixth straight portion 2h in this order toward the sixth occupancy point R6, a path along which the transport vehicles 1 travel straight from the sixth stop-point S6 toward the sixth occupancy point R6 along the sixth straight portion 2h, and a path along which the transport vehicle 1 travel from the sixth stop-point S6 through the sixth straight portion 2h, the fourth connector 2j, and the fifth straight portion 2g in this order toward the fifth occupancy point R5.

In the example shown in FIGS. 15 to 20, the entry sections 4 include the fifth stop-point S5 and a section upstream from the fifth stop-point S5 on the fifth straight portion 2g as well as the sixth stop-point S6 and a section upstream from the sixth stop-point S6 on the sixth straight portion 2h. The exit sections 5 include the fifth occupancy point R5 and a section downstream from the fifth occupancy point R5 on the fifth straight portion 2g as well as the sixth occupancy point R6 and a section downstream from the sixth occupancy point R6 on the sixth straight portion 2h. The merging area 3 includes a section between the fifth stop-point S5 and the fifth occupancy point R5 on the fifth straight portion 2g, a section between the sixth stop-point S6 and the sixth occupancy point R6 on the sixth straight portion 2h, the third connector 2i, and the fourth connector 2j.

A third example of the traffic control performed by the control system 9 will now be described with reference to FIGS. 15 to 20. In this example, four transport vehicles 1 travel on the travel path 2. The four transport vehicles 1 are a first transport vehicle A, a second transport vehicle B, a third transport vehicle C, and a fourth transport vehicle D in the order of reaching the merging area 3. In this example, the first transport vehicle A and the second transport vehicle B travel on the travel path 2 from the fifth stop-point S5 through the fifth straight portion 2g, the third connector 2i, and the sixth straight portion 2h in this order toward the sixth occupancy point R6. The third transport vehicle C then travels straight from the sixth stop-point S6 toward the sixth occupancy point R6 along the sixth straight portion 2h on the travel path 2. The fourth transport vehicle D travels straight from the fifth stop-point S5 toward the fifth occupancy point R5 along the fifth straight portion 2g on the travel path 2.

As shown in FIG. 15, the first transport vehicle A first travels along the fifth straight portion 2g toward the fifth stop-point S5. The first transport vehicle A at the fifth stop-point S5 or at a point upstream from the fifth stop-point S5 transmits the permission request N1 to the control system 9 through its communicator 13.

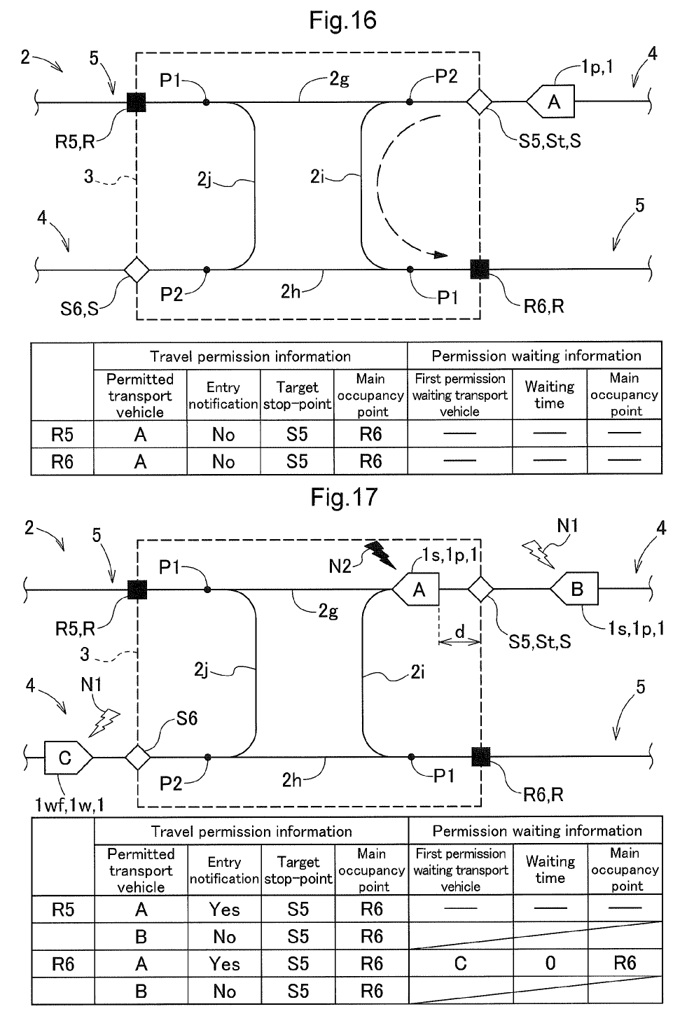

As shown in FIG. 16, in response to the permission request N1 from the first transport vehicle A, the control system 9 determines the first transport vehicle A to be the permitted transport vehicle 1p, permits the first transport vehicle A to travel from the fifth stop-point S5 to the sixth occupancy point R6 (refer to the dashed arrow in FIG. 16), and causes the sixth occupancy point R6 to enter the occupied state in which the sixth occupancy point R6 is occupied by the first transport vehicle A. The control system 9 then prohibits the transport vehicles 1 other than the first transport vehicle A from traveling from the fifth stop-point S5 to the sixth occupancy point R6. In this example, with the permitted transport vehicle 1p (the first transport vehicle A in this example) traveling along a path following the branch P2 (the third connector 2i and the sixth straight portion 2h in this example), the control system 9 causes the occupancy point R (the fifth occupancy point R5 in this example) disposed on a path extending straight through the branch P2 (the fifth straight portion 2g in this example) to enter the occupied state in addition to the occupancy point R (the sixth occupancy point R6 in this example) disposed on the path following the branch P2. In other words, the control system 9 also prohibits the transport vehicles 1 from traveling from the fifth stop-point S5 to the fifth occupancy point R5.

After permitting the first transport vehicle A to travel from the fifth stop-point S5 to the sixth occupancy point R6, the control system 9 stores, into the storage 91, the travel permission information about the sixth occupancy point R6 that is the main occupancy point. The travel permission information about the sixth occupancy point R6 includes the identification number of the first transport vehicle A as the permitted transport vehicle 1p, information indicating that the first transport vehicle A has not transmitted the entry notification N2, the address of the fifth stop-point S5 as the stop-point S (target stop-point St) to be traveled through by the first transport vehicle A, and the address of the sixth occupancy point R6 as the occupancy point R (main occupancy point) to be traveled through by the first transport vehicle A. The control system 9 also stores, into the storage 91, the travel permission information about the fifth occupancy point R5 that is the sub-occupancy point. The travel permission information about the fifth occupancy point R5 includes the identification number of the first transport vehicle A as the permitted transport vehicle 1p, information indicating that the first transport vehicle A has not transmitted the entry notification N2, the address of the fifth stop-point S5 as the stop-point S (target stop pint St) to be traveled through by the first transport vehicle A, and the address of the sixth occupancy point R6 as the occupancy point R (main occupancy point) to be traveled through by the first transport vehicle A.

The first transport vehicle A transmits, through its communicator 13, the entry notification N2 to the control system 9 on condition that the first transport vehicle A has traveled a set distance d from the fifth stop-point S5, as shown in FIG. 17. In response to the entry notification N2 from the first transport vehicle A, the control system 9 stores, into the storage 91, the travel permission information about the sixth occupancy point R6 indicating that the first transport vehicle A has transmitted the entry notification N2. The control system 9 also stores, into the storage 91, the travel permission information about the fifth occupancy point R5 indicating that the first transport vehicle A has transmitted the entry notification N2.

The second transport vehicle B following the first transport vehicle A travels along the fifth straight portion 2g toward the fifth stop-point S5, and the third transport vehicle C travels along the sixth straight portion 2h toward the sixth stop-point S6. The communicator 13 in the second transport vehicle B transmits the permission request N1 to the control system 9, and the communicator 13 in the third transport vehicle C transmits the permission request N1 to the control system 9.

In this state, the sixth occupancy point R6, which is the main occupancy point, is in the occupied state in which the sixth occupancy point R6 is occupied by the first transport vehicle A. Thus, the transport vehicles 1 other than the first transport vehicle A as the permitted transport vehicle 1p are prohibited from traveling from the fifth stop-point S5 as the target stop-point St to the sixth occupancy point R6. However, the first transport vehicle A and the second transport vehicle B are the same-path transport vehicles 1s. The control system 9 that has received the entry notification N2 from the first transport vehicle A determines, in response to the permission request N1 from the second transport vehicle B, the second transport vehicle B that is the transport vehicle 1 following the first transport vehicle A to be the permitted transport vehicle 1p and permits the second transport vehicle B to travel from the fifth stop-point S5 to the sixth occupancy point R6. The control system 9 stores, into the storage 91, the travel permission information about the sixth occupancy point R6 including the identification number of the second transport vehicle B as the permitted transport vehicle 1p, information indicating that the second transport vehicle B has not transmitted the entry notification N2, the address of the fifth stop-point S5 as the stop-point S (target stop-point St) to be traveled through by the second transport vehicle B, and the address of the sixth occupancy point R6 as the occupancy point R to be traveled through by the second transport vehicle B. The control system 9 also stores, into the storage 91, the travel permission information about the fifth occupancy point R5 including the identification number of the second transport vehicle B as the permitted transport vehicle 1p, information indicating that the second transport vehicle B has not transmitted the entry notification N2, the address of the fifth stop-point S5 as the stop-point S (target stop-point St) to be traveled through by the second transport vehicle B, and the address of the sixth occupancy point R6 as the occupancy point R to be traveled through by the second transport vehicle B.

In this example, with the sixth occupancy point R6 in the occupied state, the control system 9 also prohibits the transport vehicles 1 from traveling from the sixth stop-point S6 to the sixth occupancy point R6. In other words, the third transport vehicle C is prohibited from traveling from the sixth stop-point S6 to the sixth occupancy point R6 until the occupied state of the sixth occupancy point R6 is canceled.

The control system 9 does not permit the third transport vehicle C to travel from the sixth stop-point S6 to the sixth occupancy point R6 when receiving the permission request N1 from the third transport vehicle C. The control system 9 stores, into the storage 91, the permission waiting information about the sixth occupancy point R6 including the identification number of the third transport vehicle C as the first permission waiting transport vehicle 1wf at the sixth stop-point S6, the elapsed time after the third transport vehicle C has transmitted the permission request N1, and the address of the sixth occupancy point R6 as the occupancy point R to be traveled through by the third transport vehicle C.

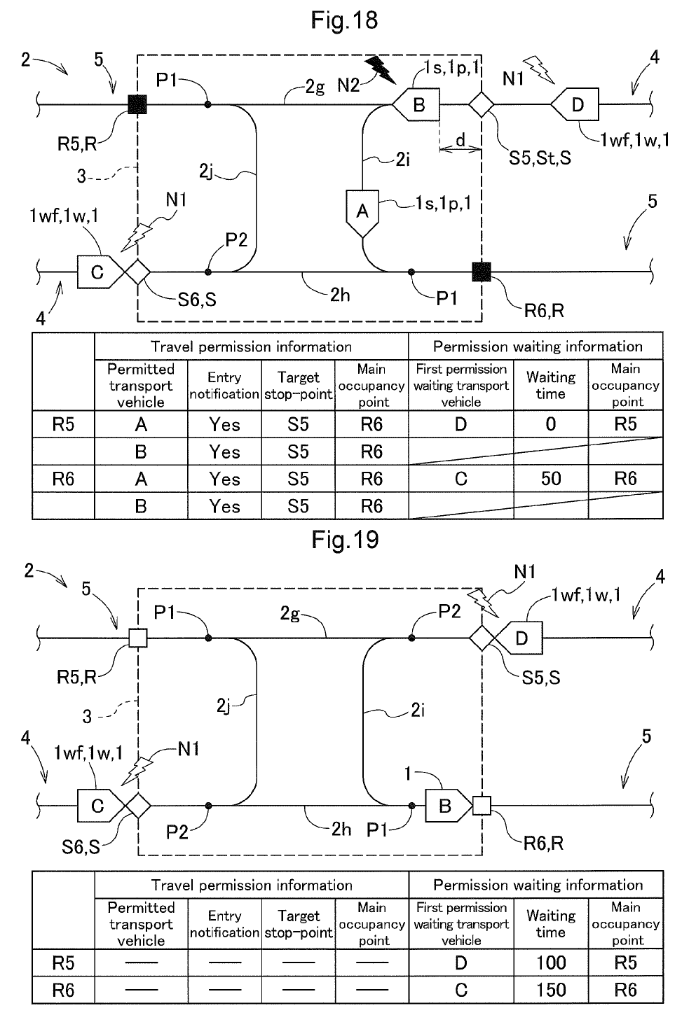

The second transport vehicle B transmits, through its communicator 13, the entry notification N2 to the control system 9 on condition that the second transport vehicle B has traveled the set distance d from the fifth stop-point S5, as shown in FIG. 18. In response to the entry notification N2 from the second transport vehicle B, the control system 9 stores, into the storage 91, the travel permission information about the sixth occupancy point R6 indicating that the second transport vehicle B has transmitted the entry notification N2. The control system 9 also stores, into the storage 91, the travel permission information about the fifth occupancy point R5 indicating that the second transport vehicle B has transmitted the entry notification N2.

The third transport vehicle C as the first permission waiting transport vehicle 1wf prohibited from traveling from the sixth stop-point S6 to the sixth occupancy point R6 stops at the sixth stop-point S6. The control system 9 then updates the permission waiting information about the third transport vehicle C (the elapsed time after the third transport vehicle C has transmitted the permission request N1 in this example) stored in the storage 91.

The fourth transport vehicle D following the second transport vehicle B also travels along the fifth straight portion 2g toward the fifth stop-point S5. The communicator 13 in the fourth transport vehicle D then transmits the permission request N1 to the control system 9.

In this state, the fifth occupancy point R5, which is the sub-occupancy point, is in the occupied state in which the fifth occupancy point R5 is occupied by the first transport vehicle A. The transport vehicles 1 are thus prohibited from traveling from the fifth stop-point S5 to the fifth occupancy point R5. The control system 9 does not permit the fourth transport vehicle D to travel from the fifth stop-point S5 to the fifth occupancy point R5 when receiving the permission request N1 from the fourth transport vehicle D. The control system 9 stores, into the storage 91, the permission waiting information about the fifth occupancy point R5 including the identification number of the fourth transport vehicle D as the first permission waiting transport vehicle 1wf at the fifth stop-point S5, the elapsed time after the fourth transport vehicle D has transmitted the permission request N1, and the address of the fifth occupancy point R5 as the occupancy point R to be traveled through by the fourth transport vehicle D.

When the second transport vehicle B as the permitted transport vehicle 1p traveling as the last one of the same-path transport vehicles 1s reaches the sixth occupancy point R6 or after the first transport vehicle A and the second transport vehicle B as the permitted transport vehicles 1p pass the sixth occupancy point R6, the control system 9 cancels the occupied state of the sixth occupancy point R6, which is the main occupancy point, and the fifth occupancy point R5, which is the sub-occupancy point, as shown in FIG. 19. The control system 9 then deletes the travel permission information about the first transport vehicle A and the second transport vehicle B. The control system 9 also updates the permission waiting information about the third transport vehicle C (the elapsed time after the third transport vehicle C has transmitted the permission request N1 in this example) and the permission waiting information about the fourth transport vehicle D (the elapsed time after the fourth transport vehicle D has transmitted the permission request N1 in this example) stored in the storage 91.

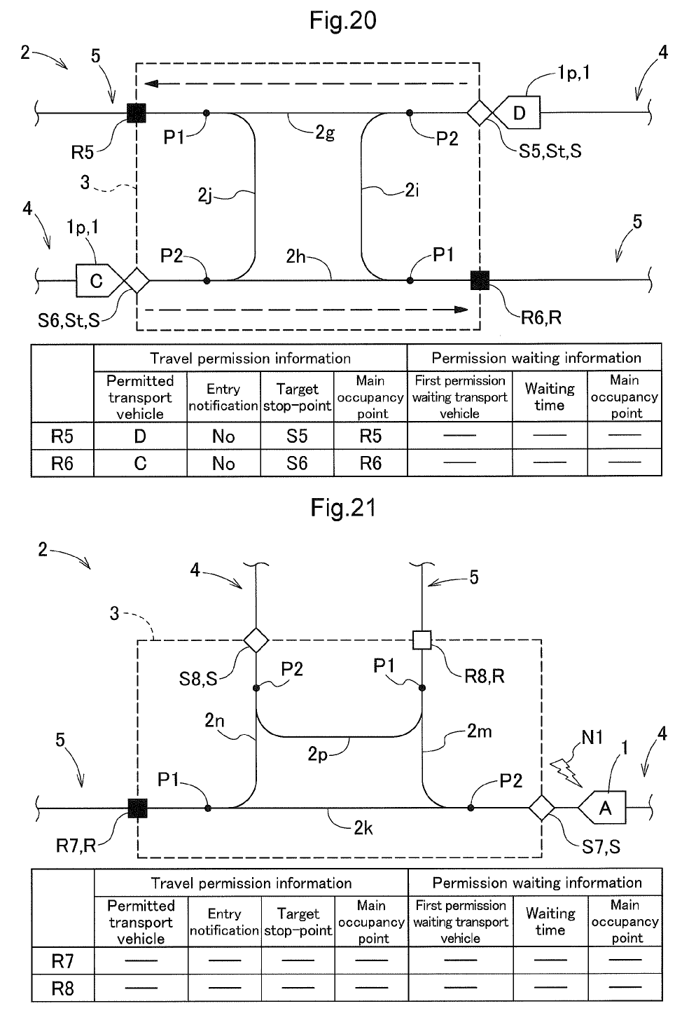

Subsequently, in response to the permission request N1 from the third transport vehicle C as the first permission waiting transport vehicle 1wf at the sixth stop-point S6, the control system 9 determines the third transport vehicle C to be the permitted transport vehicle 1p, permits the third transport vehicle C to travel from the sixth stop-point S6 to the sixth occupancy point R6 (refer to the lower dashed arrow in FIG. 20), and causes the sixth occupancy point R6 to enter the occupied state in which the sixth occupancy point R6 is occupied by the third transport vehicle C, as shown in FIG. 20. The control system 9 stores, into the storage 91, the travel permission information about the sixth occupancy point R6 including the identification number of the third transport vehicle C as the permitted transport vehicle 1p, information indicating that the third transport vehicle C has not transmitted the entry notification N2, the address of the sixth stop-point S6 as the stop-point S (target stop-point St) to be traveled through by the third transport vehicle C, and the address of the sixth occupancy point R6 as the occupancy point R to be traveled through by the third transport vehicle C.

In response to the permission request N1 from the fourth transport vehicle D as the first permission waiting transport vehicle 1wf at the fifth stop-point S5, the control system 9 also determines the fourth transport vehicle D to be the permitted transport vehicle 1p, permits the fourth transport vehicle D to travel from the fifth stop-point S5 to the fifth occupancy point R5 (refer to the upper dashed arrow in FIG. 20), and causes the fifth occupancy point R5 to enter the occupied state in which the fifth occupancy point R5 is occupied by the fourth transport vehicle D. The control system 9 stores, into the storage 91, the travel permission information about the fifth occupancy point R5 including the identification number of the fourth transport vehicle D as the permitted transport vehicle 1p, information indicating that the fourth transport vehicle D has not transmitted the entry notification N2, the address of the fifth stop-point S5 as the stop-point S (target stop-point St) to be traveled through by the fourth transport vehicle D, and the address of the fifth occupancy point R5 as the occupancy point R to be traveled through by the fourth transport vehicle D. The subsequent operation of the control system 9 will not be described.

FIGS. 21 to 24 show a fourth example layout of the merging area 3, the entry sections 4, and the exit section 5. In this example, a single merging area 3, two entry sections 4, and two exit sections 5 are arranged.

In the example shown in FIGS. 21 to 24, the travel path 2 includes a seventh straight portion 2k, a first path portion 2m, a second path portion 2n, and a fifth connector 2p. The seventh straight portion 2k extends straight. The first path portion 2m branches from the seventh straight portion 2k at the branch P2 disposed along the seventh straight portion 2k. The first path portion 2m extends perpendicular to the seventh straight portion 2k. The second path portion 2n extends perpendicular to the seventh straight portion 2k and merges, from the side on which the first path portion 2m is disposed relative to the seventh straight portion 2k, with the seventh straight portion 2k at the junction P1 disposed downstream from the branch P2 on the seventh straight portion 2k. The fifth connector 2p branches from the second path portion 2n at the branch P2 disposed upstream from the junction P1 on the second path portion 2n and merges with the first path portion 2m at the junction P1 disposed downstream from the branch P2 on the first path portion 2m.

In the example shown in FIGS. 21 to 24, the seventh straight portion 2k includes a seventh stop-point S7 as the stop-point S upstream from the connection point (branch P2) of the first path portion 2m and seventh straight portion 2k. The seventh straight portion 2k includes a seventh occupancy point R7 as the occupancy point R downstream from the connection point (junction P1) of the second path portion 2n and the seventh straight portion 2k. The second path portion 2n includes an eighth stop-point S8 as the stop-point S upstream from the connection point (branch P2) of the fifth connector 2p and the second path portion 2n. The first path portion 2m includes an eighth occupancy point R8 as the occupancy point R downstream from the connection point (junction P1) of the fifth connector 2p and the second path portion 2n. In this example, the travel path 2 includes a path along which the transport vehicles 1 travel from the seventh stop-point S7 toward the seventh occupancy point R7 along the seventh straight portion 2k, a path along which the transport vehicles 1 travel from the seventh stop-point S7 through the seventh straight portion 2k and the first path portion 2m in this order toward the eighth occupancy point R8, a path along which the transport vehicles 1 travel from the eighth stop-point S8 through the second path portion 2n and the seventh straight portion 2k in this order toward the seventh occupancy point R7, and a path along which the transport vehicles 1 travel from the eighth stop-point S8 through the second path portion 2n, the fifth connector 2p, and the first path portion 2m in this order toward the eighth occupancy point R8.

In the example shown in FIGS. 21 to 24, the entry sections 4 include the seventh stop-point S7 and a section upstream from the seventh stop-point S7 on the seventh straight portion 2k as well as the eighth stop-point S8 and a section upstream from the eighth stop-point S8 on the second path portion 2n. The exit sections 5 include the seventh occupancy point R7 and a section downstream from the seventh occupancy point R7 on the seventh straight portion 2k as well as the eighth occupancy point R8 and a section downstream from the eighth occupancy point R8 on the first path portion 2m. The merging area 3 includes a section between the seventh stop-point S7 and the seventh occupancy point R7 on the seventh straight portion 2k, a section between the branch P2 and the eighth occupancy point R8 on the first path portion 2m, a section between the eighth stop-point S8 and the junction P1 on the second path portion 2n, and the fifth connector 2p.

A fourth example of the traffic control performed by the control system 9 will now be described with reference to FIGS. 21 to 24. In this example, three transport vehicles 1 travel on the travel path 2. The three transport vehicles 1 are a first transport vehicle A, a second transport vehicle B, and a third transport vehicle C in the order of reaching the merging area 3. In this example, the first transport vehicle A and the second transport vehicle B travel straight from the seventh stop-point S7 toward the seventh occupancy point R7 along the seventh straight portion 2k on the travel path 2. The third transport vehicle C travels from the eighth stop-point S8 through the second path portion 2n, the fifth connector 2p, and the first path portion 2m in this order toward the eighth occupancy point R8 on the travel path 2.

As shown in FIG. 21, the first transport vehicle A first travels along the seventh straight portion 2k toward the seventh stop-point S7. The first transport vehicle A at the seventh stop-point S7 or at a point upstream from the seventh stop-point S7 transmits the permission request N1 to the control system 9 through its communicator 13.

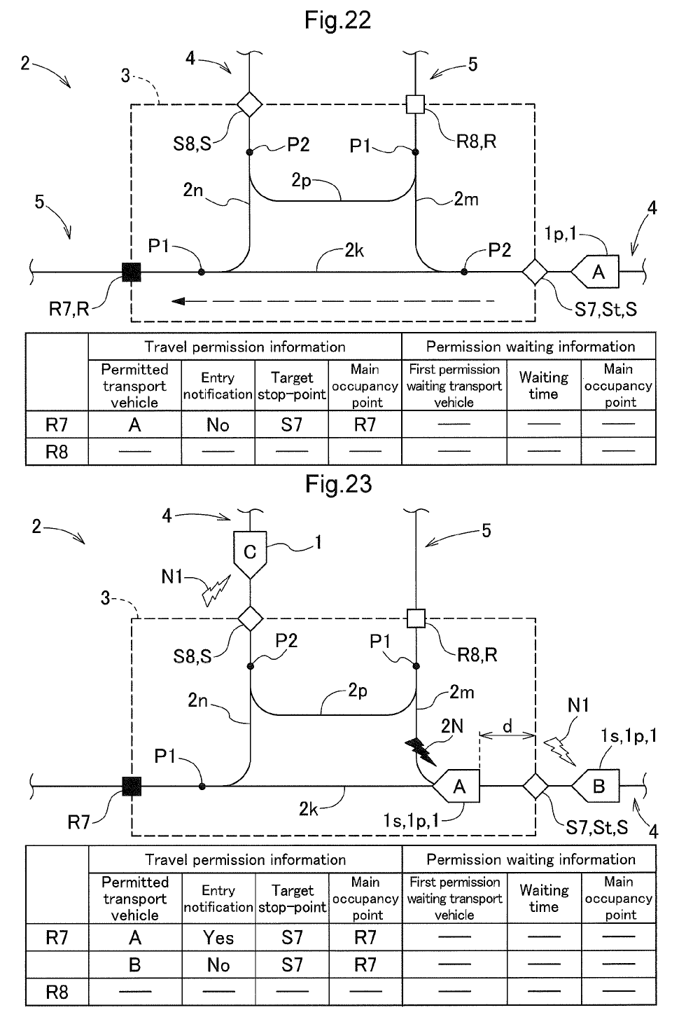

As shown in FIG. 22, in response to the permission request N1 from the first transport vehicle A, the control system 9 determines the first transport vehicle A to be the permitted transport vehicle 1p, permits the first transport vehicle A to travel from the seventh stop-point S7 to the seventh occupancy point R7 (refer to the dashed arrow in FIG. 22), and causes the seventh occupancy point R7 to enter the occupied state in which the seventh occupancy point R7 is occupied by the first transport vehicle A. The control system 9 then prohibits the transport vehicles 1 other than the first transport vehicle A from traveling from the seventh stop-point S7 to the seventh occupancy point R7. In this example, the control system 9 causes only the main occupancy point (the seventh occupancy point R7 in this example) of the permitted transport vehicle 1p (the first transport vehicle A in this example) to enter the occupied state.

After permitting the first transport vehicle A to travel from the seventh stop-point S7 to the seventh occupancy point R7, the control system 9 stores, into the storage 91, the travel permission information about the seventh occupancy point R7 that is the main occupancy point. The travel permission information about the seventh occupancy point R7 includes the identification number of the first transport vehicle A as the permitted transport vehicle 1p, information indicating that the first transport vehicle A has not transmitted the entry notification N2, the address of the seventh stop-point S7 as the stop-point S (target stop-point St) to be traveled through by the first transport vehicle A, and the address of the seventh occupancy point R7 as the occupancy point R (main occupancy point) to be traveled through by the first transport vehicle A.

The first transport vehicle A transmits, through its communicator 13, the entry notification N2 to the control system 9 on condition that the first transport vehicle A has traveled a set distance d from the seventh stop-point S7, as shown in FIG. 23. In response to the entry notification N2 from the first transport vehicle A, the control system 9 stores, into the storage 91, the travel permission information about the seventh occupancy point R7 indicating that the first transport vehicle A has transmitted the entry notification N2.

The second transport vehicle B following the first transport vehicle A travels along the seventh straight portion 2k toward the seventh stop-point S7, and the third transport vehicle C travels along the second path portion 2n toward the eighth stop-point S8. The communicator 13 in the second transport vehicle B transmits the permission request N1 to the control system 9, and the communicator 13 in the third transport vehicle C transmits the permission request N1 to the control system 9.

In this state, the seventh occupancy point R7, which is the main occupancy point, is in the occupied state in which the seventh occupancy point R7 is occupied by the first transport vehicle A. Thus, the transport vehicles 1 other than the first transport vehicle A as the permitted transport vehicle 1p are prohibited from traveling from the seventh stop-point S7 as the target stop-point St to the seventh occupancy point R7. However, the first transport vehicle A and the second transport vehicle B are the same-path transport vehicles 1s. The control system 9 that has received the entry notification N2 from the first transport vehicle A determines, in response to the permission request N1 from the second transport vehicle B, the second transport vehicle B that is the transport vehicle 1 following the first transport vehicle A to be the permitted transport vehicle 1p and permits the second transport vehicle B to travel from the seventh stop-point S7 to the seventh occupancy point R7. The control system 9 stores, into the storage 91, the travel permission information about the seventh occupancy point R7 including the identification number of the second transport vehicle B as the permitted transport vehicle 1p, information indicating that the second transport vehicle B has not transmitted the entry notification N2, the address of the seventh stop-point S7 as the stop-point S (target stop-point St) to be traveled through by the second transport vehicle B, and the address of the seventh occupancy point R7 as the occupancy point R to be traveled through by the second transport vehicle B.

In this example, with the seventh occupancy point R7 in the occupied state, the control system 9 also prohibits the transport vehicles 1 from traveling from the eighth stop-point S8 to the seventh occupancy point R7. However, with the eighth occupancy point R8 not in the occupied state, the control system 9 does not prohibit the transport vehicles 1 from traveling from the eighth stop-point S8 to the eighth occupancy point R8.

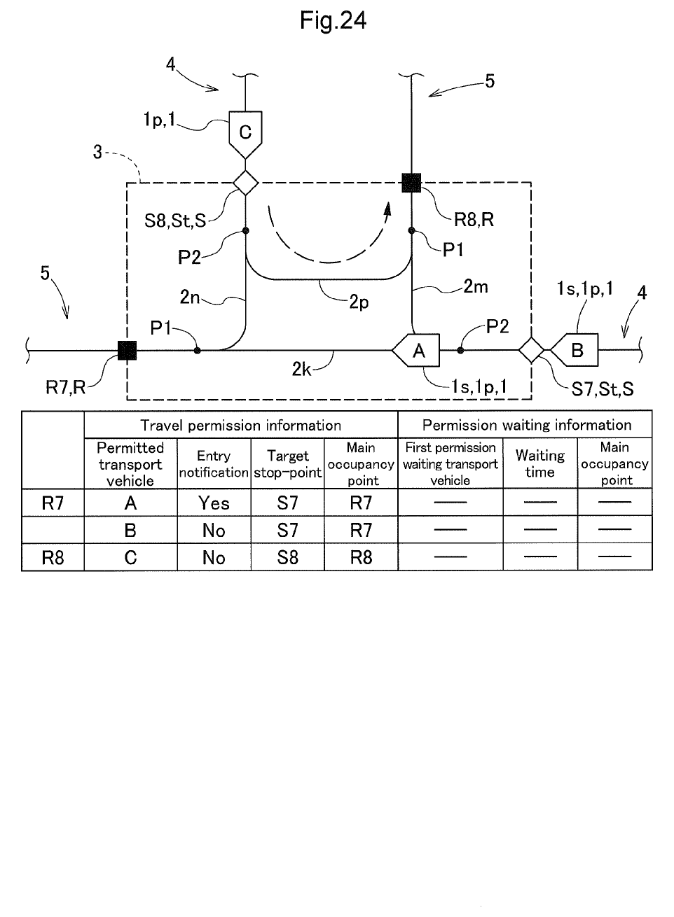

As shown in FIG. 24, in response to the permission request N1 from the third transport vehicle C, the control system 9 determines the third transport vehicle C to be the permitted transport vehicle 1p, permits the third transport vehicle C to travel from the eighth stop-point S8 to the eighth occupancy point R8 (refer to the dashed arrow in FIG. 24), and causes the eighth occupancy point R8 to enter the occupied state in which the eighth occupancy point R8 is occupied by the third transport vehicle C. The control system 9 then prohibits the transport vehicles 1 other than the third transport vehicle C from traveling from the eighth stop-point S8 to the eighth occupancy point R8.

After permitting the third transport vehicle C to travel from the eighth stop-point S8 to the eighth occupancy point R8, the control system 9 stores, into the storage 91, the travel permission information about the eighth occupancy point R8 that is the main occupancy point. The travel permission information about the eighth occupancy point R8 includes the identification number of the third transport vehicle C as the permitted transport vehicle 1p, information indicating that the third transport vehicle C has not transmitted the entry notification N2, the address of the eighth stop-point S8 as the stop-point S (target stop-point St) to be traveled through by the third transport vehicle C, and the address of the eighth occupancy point R8 as the occupancy point R (main occupancy point) to be traveled through by the third transport vehicle C. The subsequent operation of the control system 9 will not be described.

### Other Embodiments

(1) In the above embodiment, each transport vehicle 1 is a ceiling-hung transport vehicle that travels along the travel path 2 defined by rails hung from the ceiling. In some embodiments, the transport vehicle 1 may be, for example, a tracked transport vehicle that travels along a travel path 2 defined by rails on the floor surface. The transport vehicle 1 may be a trackless transport vehicle that travels along a travel path 2 defined virtually. In this case, the travel path 2 can be defined by multiple detectable members (e.g., two-dimensional codes, radio frequency tags or RF tags, or magnetic tape). The travel path 2 may also be virtually defined, without such detectable members, based on a route calculated using recognition results of the surrounding environment.

(2) In the above embodiment, the first transport vehicle A and the second transport vehicle B are the same-path transport vehicles 1s. In some embodiments, the first transport vehicle A, the second transport vehicle B, and the third transport vehicle C may be, for example, the same-path transport vehicles 1s. In this case, the first transport vehicle A, the second transport vehicle B, and the third transport vehicle C may all be determined to be the permitted transport vehicles 1p, or the first transport vehicle A and the second transport vehicle B may be determined to be the permitted transport vehicles 1p without the third transport vehicle C being determined to be the permitted transport vehicle 1p.

(3) The structure described in each of the above embodiments may be combined with any other structures described in the other embodiments unless any contradiction arises. For other structures as well, the embodiments described herein are merely illustrative in all aspects. Thus, the embodiments described herein may be modified variously as appropriate without departing from the spirit and scope of the disclosure.

### Overview of Present Embodiment

An overview of the transport facility described above is provided below.

A transport facility includes a plurality of transport vehicles, a travel path along which the plurality of transport vehicles travel, and a control system that controls the plurality of transport vehicles. The travel path includes a merging area including a junction at which a plurality of paths merge, a plurality of entry sections through which the plurality of transport vehicles enter the merging area, and an exit section through which the plurality of transport vehicles exit the merging area. The plurality of entry sections respectively include a plurality of stop-points. The exit section includes an occupancy point. The control system performs traffic control in permitting, among the plurality of transport vehicles, at least one transport vehicle at a target stop-point among the plurality of stop-points or at a point upstream from the target stop-point to travel through the merging area. The traffic control includes causing the occupancy point to enter an occupied state in which the occupancy point is occupied by at least one permitted transport vehicle that is the at least one transport vehicle permitted to travel through the merging area, prohibiting, during the occupancy point being in the occupied state, the plurality of transport vehicles other than the at least one permitted transport vehicle from traveling at least from the target stop-point to the occupancy point occupied by the at least one permitted transport vehicle, and canceling the occupied state after the at least one permitted transport vehicle passes the occupancy point. During the traffic control, the control system performs a sequential travel-permission process when a plurality of transport vehicles traveling to the merging area among the plurality of transport vehicles include a plurality of same-path transport vehicles having a same combination of the occupancy point and a stop-point to travel through among the plurality of stop-points. The sequential travel-permission process is a process to permit the plurality of same-path transport vehicles to sequentially travel through the merging area.

In this structure, the sequential travel-permission process can shorten the distance between the multiple same-path transport vehicles traveling through the merging area. This allows more transport vehicles to travel through the merging area per unit time. Thus, the travel efficiency of the transport vehicles in the merging area is increased, increasing the transport efficiency of the transport facility.

The at least one permitted transport vehicle may transmit an entry notification to the control system on condition that the at least one permitted transport vehicle has traveled a set distance from the target stop-point. During the sequential travel-permission process, the control system may permit, in response to the entry notification, a transport vehicle as one of the plurality of same-path transport vehicles and following the at least one permitted transport vehicle that has transmitted the entry notification to travel through the merging area.

In this structure, the multiple same-path transport vehicles can sequentially travel through the merging area with an appropriate distance between the transport vehicles.

The at least one permitted transport vehicle may include a plurality of permitted transport vehicles. The control system may store travel permission information about the plurality of permitted transport vehicles. The travel permission information may include information indicating the stop-point and the occupancy point to be traveled through by each of the plurality of permitted transport vehicles.

In this structure, multiple transport vehicles can be provided with the travel permission more promptly and controlled more appropriately than in a structure in which the travel permission information about only a single permitted transport vehicle is stored.

In the structure in which the control system stores the travel permission information, the at least one permitted transport vehicle may transmit an entry notification to the control system on condition that the at least one permitted transport vehicle has traveled a set distance from the target stop-point. During the sequential travel-permission process, the control system may permit, in response to the entry notification, a transport vehicle as one of the plurality of same-path transport vehicles and following the at least one permitted transport vehicle that has transmitted the entry notification to travel through the merging area. The travel permission information may further include information indicating whether the entry notification is received from each of the plurality of permitted transport vehicles.

In this structure, the determination is appropriately performed as to whether each of the multiple permitted transport vehicles has passed a point at a set distance from the target stop-point.

In the structure in which the control system stores the travel permission information, each of the plurality of transport vehicles at the stop-point or at a point upstream from the stop-point may transmit, to the control system, a permission request to travel through the merging area. The control system may store permission waiting information about at least one permission waiting transport vehicle that is the at least one transport vehicle that has transmitted the permission request and has not been permitted to travel through the merging area. The permission waiting information may include information indicating the occupancy point to be traveled through by the at least one permission waiting transport vehicle and information indicating an elapsed time after the at least one permission waiting transport vehicle has transmitted the permission request.

In this structure, travel permission can be provided in an appropriate order to multiple permission waiting transport vehicles based on the elapsed time after each of the multiple permission waiting transport vehicles has transmitted the corresponding permission request.

### INDUSTRIAL APPLICABILITY

The technique according to one or more embodiments of the disclosure can be used for a transport facility including multiple transport vehicles, a travel path along which the multiple transport vehicles travel, and a control system that controls the multiple transport vehicles.

What is claimed is:

1. A transport facility, comprising:
a plurality of transport vehicles;
a travel path along which the plurality of transport vehicles travel; and
a control system configured to control the plurality of transport vehicles, and
wherein:
the travel path comprises a merging area including a junction at which a plurality of paths merge, a plurality of entry sections through which the plurality of transport vehicles enter the merging area, and an exit section through which the plurality of transport vehicles exit the merging area,
the plurality of entry sections respectively comprises a plurality of stop-points,
the exit section comprises an occupancy point,
the control system is configured to perform traffic control in permitting, among the plurality of transport vehicles, at least one transport vehicle at a target stop-point among the plurality of stop-points or at a point upstream from the target stop-point to travel through the merging area, the traffic control including causing the occupancy point to enter an occupied state in which the occupancy point is occupied by at least one permitted transport vehicle that is the at least one transport vehicle permitted to travel through the merging area, prohibiting, during the occupancy point being in the occupied state, the plurality of transport vehicles other than the at least one permitted transport vehicle from traveling at least from the target stop-point to the occupancy point occupied by the at least one permitted transport vehicle, and canceling the occupied state after the at least one permitted transport vehicle passes the occupancy point, and
during the traffic control, the control system is configured to perform a sequential travel-permission process when a plurality of transport vehicles traveling to the merging area among the plurality of transport vehicles comprise a plurality of same-path transport vehicles having a same combination of the occupancy point and a stop-point to travel through among the plurality of stop-points, the sequential travel-permission process comprising a process to permit the plurality of same-path transport vehicles to sequentially travel through the merging area.

2. The transport facility according to claim 1, wherein:
the at least one permitted transport vehicle transmits an entry notification to the control system on condition that the at least one permitted transport vehicle has traveled a set distance from the target stop-point, and
during the sequential travel-permission process, the control system permits, in response to the entry notification, a transport vehicle as one of the plurality of same-path transport vehicles and following the at least one permitted transport vehicle that has transmitted the entry notification to travel through the merging area.

3. The transport facility according to claim 1, wherein:
the at least one permitted transport vehicle comprises a plurality of permitted transport vehicles,
the control system stores travel permission information about the plurality of permitted transport vehicles, and
the travel permission information comprises information indicating the stop-point and the occupancy point to be traveled through by each of the plurality of permitted transport vehicles.

4. The transport facility according to claim 3, wherein:
the at least one permitted transport vehicle transmits an entry notification to the control system on condition that the at least one permitted transport vehicle has traveled a set distance from the target stop-point,
during the sequential travel-permission process, the control system permits, in response to the entry notification, a transport vehicle as one of the plurality of same-path transport vehicles and following the at least one permitted transport vehicle that has transmitted the entry notification to travel through the merging area, and
the travel permission information further comprises information indicating whether the entry notification is received from each of the plurality of permitted transport vehicles.

5. The transport facility according to claim 3, wherein:
each of the plurality of transport vehicles at the stop-point or at a point upstream from the stop-point transmits, to the control system, a permission request to travel through the merging area,
the control system stores permission waiting information about at least one permission waiting transport vehicle that is the at least one transport vehicle that has transmitted the permission request and has not been permitted to travel through the merging area, and
the permission waiting information comprises information indicating the occupancy point to be traveled through by the at least one permission waiting transport vehicle and information indicating an elapsed time after the at least one permission waiting transport vehicle has transmitted the permission request.
